(19) United States
(12) Patent Application Publication
(10) Pub. No.: US 2011/0030766 A1
(43) Pub. Date: Feb. 10, 2011

(54) Solar energy utilizing apparatuses and methods of manufacturing the same

(75) Inventors: Hyung-bin Son, Seoul (KR); Jong-min Kim, Suwon-si (KR); Young-jun Park, Suwon-si (KR); Seung-nam Cha, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/659,154

(22) Filed: Feb. 26, 2010

(30) Foreign Application Priority Data
Aug. 5, 2009 (KR) 10-2009-0072117

(51) Int. Cl. H01L 31/058; H01L 31/00; H01L 31/18

(52) U.S. Cl. 136/248; 136/252; 438/66; 257/E31.131

(57) ABSTRACT

A solar energy utilizing apparatus includes: a fluid pipe forming a flow path of a heat medium and including a convex surface; and a solar cell formed on the convex surface of the fluid pipe. In a method of manufacturing a solar energy utilizing apparatus, a first substrate including a first surface and a second surface is formed. The first surface has a plurality of convex surfaces and the second surface has a plurality of concave surfaces. A plurality of solar cells are formed on the convex surfaces, respectively. A second substrate is formed, and the second substrate is bonded to the first substrate.

### CROSS-REFERENCE TO RELATED APPLICATION(S)

This application claims priority under 35 U.S.C. §119 to Korean Patent Application No. 10-2009-0072117, filed on Aug. 5, 2009, in the Korean Intellectual Property Office, the disclosure of which is incorporated herein in its entirety by reference.

### BACKGROUND

1. Field

Example embodiments relate to relatively complex solar energy utilizing apparatuses and methods of manufacturing the same.

2. Description of the Related Art

Research is being conducted into alternative energy technologies to replace fossil fuel energy. Alternative energy technologies utilize energy sources such as solar energy, Earth heat, tidal power, etc. Solar energy technology uses solar energy, which is relatively limitless and environmentally friendly. Thus, solar energy does not incur the fuel costs of fossil fuels and does not generate air pollution or waste.

Solar energy technology is divided into technology using solar heat and technology using solar light. An example of solar light technology is a solar cell, which is a semiconductor device that converts solar light into electricity. Semiconductor devices also use photovoltaic effects, which are referred to as photovoltaic (PV) cells. Solar heat is used as heat energy to heat facilities.

Recently, a hybrid system capable of utilizing both solar heat and solar light has been recognized as more energy efficient.

### SUMMARY

Example embodiments provide relatively complex solar energy utilizing apparatuses capable of generating both electrical energy and heat energy from solar energy to increase energy efficiency. Example embodiments also provide methods of manufacturing solar energy utilizing apparatuses.

At least one example embodiment provides a solar energy utilizing apparatus. According to at least this example embodiment, the apparatus includes: a fluid pipe and a solar cell. The fluid pipe is configured to form a flow path for a heat medium and includes a convex surface. The solar cell is formed on the convex surface of the fluid pipe.

According to at least one other example embodiment, a solar energy utilizing apparatus includes: a first substrate; a plurality of solar cells; and a second substrate. The first substrate includes: a first surface on which a plurality of convex surfaces are formed; and a second surface on which a plurality of concave surfaces are formed. The plurality of concave surfaces correspond to the plurality of convex surfaces to form a plurality of grooves. The plurality of solar cells are respectively formed on the plurality of the convex surfaces. The second substrate is bonded to the first substrate. A plurality of inner spaces are formed by bonding the first substrate and the second substrate. The plurality of inner spaces form a flow path for a heat medium.

According to at least some example embodiments, the second substrate may also include a plurality of grooves. The first substrate and the second substrate may be bonded to each other such that the grooves of the first substrate and the grooves of the second substrate face each other. The second substrate may have a plurality of convex surfaces and a plurality of concave surfaces of the same or substantially the same structure as the first substrate. The first substrate and the second substrate may be symmetrically bonded to each other about a bonding surface.

A solar cell may be further formed on the plurality of convex surfaces of the second substrate. Alternatively, a light absorption layer may be formed on the plurality of convex surfaces of the second substrate. The plurality of inner spaces may be connected to one another to form a single flow path.

According to at least some example embodiments, the solar energy utilizing apparatus may further include: a sealing member surrounding the plurality of solar cells and protecting or insulating the solar cells from external environmental factors.

A plurality of through holes may be formed through the first and second substrates.

At least one other example embodiment provides a method of manufacturing a solar energy utilizing apparatus. According to at least this example embodiment, a first substrate including a first surface and a second surface is formed. A plurality of convex surfaces are formed on the first surface and a plurality of concave surfaces corresponding to the plurality of convex surfaces are formed on a second surface. The concave and convex surfaces form a plurality of grooves. A plurality of solar cells are formed on the plurality of convex surfaces, respectively. A second substrate is formed and bonded to the first substrate.

According to at least some example embodiments, the first substrate and the second substrate may be bonded to each other by: forming a plurality of grooves in the second substrate; and bonding the first substrate to the second substrate such that the plurality of grooves of the first substrate and the plurality of grooves of the second substrate face each other. Alternatively, the first substrate and the second substrate may be bonded to each other by: forming the plurality of grooves of the second substrate with a plurality of convex surfaces and a plurality of concave surfaces having the same or substantially the same structure as the convex and concave surfaces of the first substrate; and bonding the first substrate and the second substrate to each other symmetrically about a bonding surface.

According to at least some example embodiments, a solar cell may be formed on the plurality of convex surfaces of the second substrate. Alternatively, a light absorption layer may be formed on the plurality of convex surfaces of the second substrate. A sealing member may also be formed. The sealing member may surround the plurality of solar cells to protect or insulate the solar cells from external environmental factors A plurality of through holes may be formed through the first and second substrates.

### BRIEF DESCRIPTION OF THE DRAWINGS

Example embodiments will become apparent and more readily appreciated from the following description of the accompanying drawings of which:

FIG. 1 is a perspective view illustrating a solar energy utilizing apparatus according to an example embodiment;

FIG. 2A is a perspective view illustrating a structure of a solar energy utilizing apparatus according to another example embodiment;

FIG. 2B is a cross-sectional view taken along line A-A′ in FIG. 2A;

FIG. 3 is a cross-sectional view illustrating a solar energy utilizing apparatus according to another example embodiment;

FIG. 4 is a cross-sectional view illustrating a solar energy utilizing apparatus according to another example embodiment;

FIG. 5 is a cross-sectional view illustrating a solar energy utilizing apparatus according to another example embodiment;

FIG. 6A is a plane view of a structure of a solar energy utilizing apparatus according to another example embodiment;

FIG. 6B is a cross-sectional view taken along line B-B′ in FIG. 6A;

FIGS. 7A through 7D are cross-sectional views illustrating a method of manufacturing a solar energy utilizing apparatus according to an example embodiment; and

FIGS. 8A through 8E are cross-sectional views illustrating a method of manufacturing a solar energy utilizing apparatus according to another example embodiment.

### DETAILED DESCRIPTION

Inventive concepts will now be described more fully with reference to the accompanying drawings, in which example embodiments are shown. In the drawings, the thicknesses of layers and regions are exaggerated for clarity. Like reference numerals in the drawings denote like elements.

Detailed illustrative embodiments are disclosed herein. However, specific structural and functional details disclosed herein are merely representative for purposes of describing example embodiments. Inventive concepts may, however, may be embodied in many alternate forms and should not be construed as limited to only the example embodiments set forth herein.

It should be understood that there is no intent to limit inventive concepts to the particular example embodiments disclosed, but on the contrary example embodiments are to cover all modifications, equivalents, and alternatives falling within the scope of inventive concepts. Like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items.

When an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting. As used herein, the singular forms “a,” “an,” and “the,” are intended to include the plural forms as well, unless the context clearly indicates otherwise. It will be further understood that the terms “comprises,” “comprising,” “includes,” and/or “including,” if used herein, specify the presence of stated features, integers, steps, operations, elements and/or components, but do not preclude the presence or addition of one or more other features, integers, steps, operations, elements, components and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

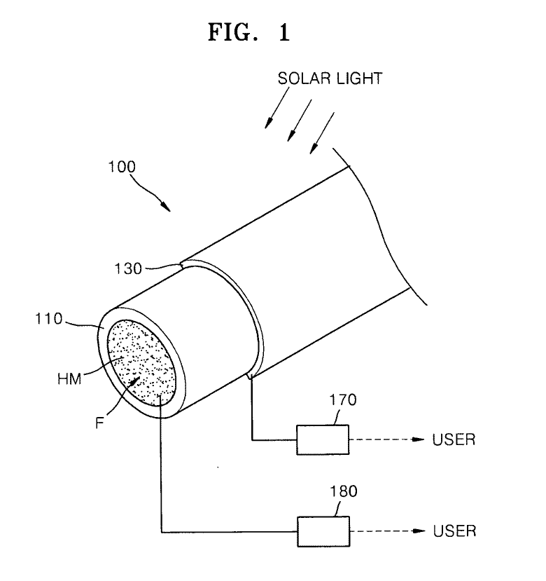

FIG. 1 is a schematic perspective view illustrating a solar energy utilizing apparatus according to an example embodiment.

Referring to FIG. 1, the solar energy utilizing apparatus 100 includes a fluid pipe 110 and a solar cell 130. The fluid pipe 110 may serve as a flow path F for a heat medium HM. The solar cell 130 is formed on a convex surface of the fluid pipe 110.

In this example embodiment, the solar cell 130 is in the form of a thin film cell, and is formed on the convex surface of the fluid pipe 110. More specifically, in FIG. 1, the solar cell 130 is formed on a portion of the convex surface of the fluid pipe 110. However, example embodiments are not limited thereto. The solar cell 130 may also be formed to surround the entire convex surface of the fluid pipe 110.

The solar cell 130 generates electricity by using solar light. The solar cell 130 may be formed of a crystalline silicon semiconductor, an amorphous silicon semiconductor, or various types of compound semiconductors.

According to at least this example embodiment, when solar light is irradiated at a P-N junction structure of a semiconductor, pairs of electrons and holes are generated by solar light energy according to the photovoltaic effect. The electrons and holes move across an N layer and a P layer to generate a current, thereby generating electromotive force. The current flows through an externally connected load due to the electromotive force.

Still referring to FIG. 1, the solar energy utilizing apparatus 100 may further include a power supplementing unit (or circuit) 170. The power supplementing unit 170 may be, for example, a storage battery that stores power generated by the solar cell 130, a power adjuster, a direct-current/alternating current (DC/AC) converter, etc. The power generated by the solar cell 130 may pass through the power supplementing unit 170 and be supplied to users.

The fluid pipe 110 collects solar heat and forms the flow path F through which the heat medium HM flows. The heat medium HM may be heated by solar heat. The fluid pipe 110 may be formed of a transparent material such as glass or other material. To increase an adiabatic effect, a vacuum pipe structure may be used as the fluid pipe 110. A layer for enhancing light absorption may be coated on an inner surface of the fluid pipe 110 to increase a heat collecting effect. The flow path F of the fluid pipe 110 illustrated in FIG. 1 has a round cross-section, but example embodiments are not limited thereto. Rather, the cross-section of the flow path F may have various shapes. Examples of the heat medium HM include: an anti-freeze solution, water, oil, etc. The heat medium HM may be supplied to the fluid pipe 110 through an inlet unit (not shown) and may be heated by solar heat.

The solar energy utilizing apparatus 100 may further include a hot water tank 180. The hot water tank 180 collects the heated heat medium HM, and may supply hot water to one or more users such as a heating facility.

When generating electricity from solar light and collecting solar heat at the same time (e.g., simultaneously or concurrently), total energy conversion efficiency may increase. Also, a temperature of the solar cell 130 may decrease by the heat medium HM supplied to the fluid pipe 110 to collect heat, thereby increasing the electricity generation efficiency and the life span of the solar cell 130.

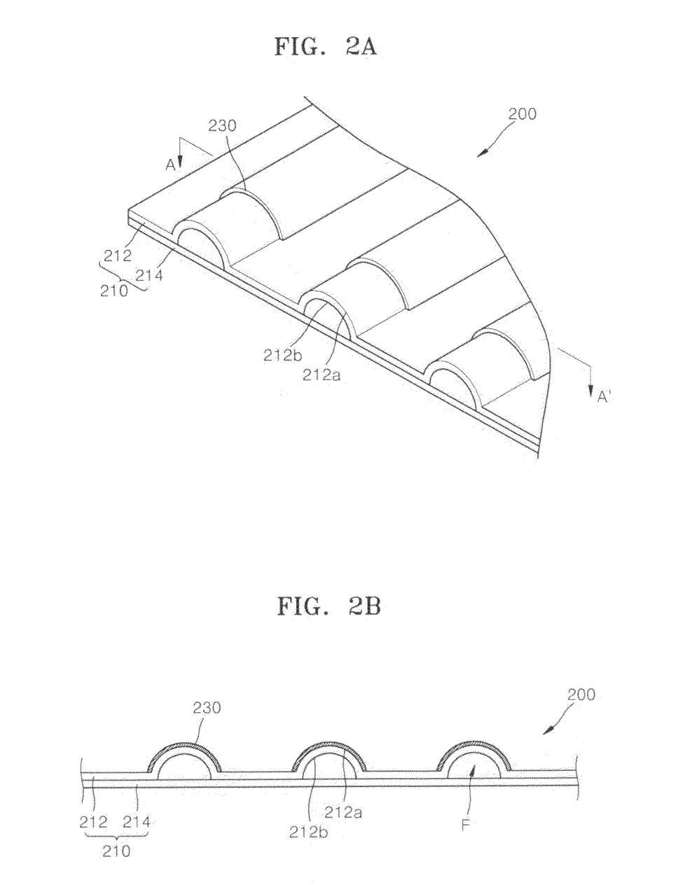

FIG. 2A is a perspective view illustrating a structure of a solar energy utilizing apparatus according to another example embodiment. FIG. 2B is a cross-sectional view taken along line A-A′ of FIG. 2A.

Referring to FIGS. 2A and 2B, the solar energy utilizing apparatus 200 includes: a fluid pipe 210 and a solar cell 230 formed on a portion of a surface of the fluid pipe 210. The fluid pipe 210 includes a first substrate 212 and a flat second substrate 214 that is bonded to the first substrate 212. The first substrate 212 includes a plurality of grooves. A plurality of convex surfaces 212a are formed on a surface of the first substrate 212. A plurality of concave surfaces 212b corresponding to the plurality of the convex surfaces 212a are formed on the other surface of the first substrate 212. The convex and concave surfaces 212a and 212b form a plurality of grooves. As the first substrate 212 and the second substrate 214 are bonded to each other, a plurality of inner spaces are formed between the first substrate 212 and the second substrate 214, thereby forming a flow path F for a heat medium.

In FIGS. 2A and 2B, both surfaces of the second substrate 214 are flat; however, example embodiments are not limited thereto. For example, the second substrate 214 may have various shapes, which may form a flow path F when bonded to the first substrate 212. For example, one surface of the second substrate 214 may be flat, and the other surface thereof may be formed with a plurality of grooves. In this case, the first substrate 212 and the second substrate 214 may be bonded such that the grooves of the first substrate 212 and the grooves of the second substrate 214 face or correspond to each other. The solar cell 230 is formed on the convex surfaces 212a of the first substrate 212.

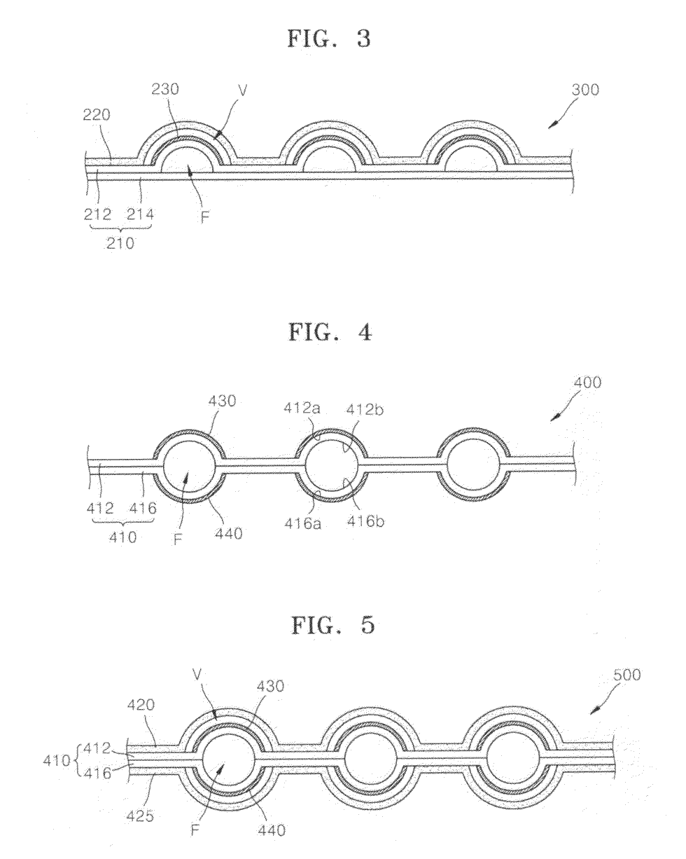

FIG. 3 is a cross-sectional view illustrating a solar energy utilizing apparatus according to another embodiment. The solar energy utilizing apparatus 300 is similar to the solar energy utilizing apparatus 200 shown in FIGS. 2A and 2B except that the solar energy utilizing apparatus 300 further includes a sealing member 220. The sealing member 220 protects and/or insulates the solar cell 230 from the outside. More specifically, for example, the sealing member 220 protects the solar cell 230 from external environmental factors such as water, oxygen and/or to obtain adiabatic effects for increasing the heat collecting efficiency of the solar energy utilizing apparatus 300. The sealing member 220 may also vacuum-seal the solar cell 230, and may be formed of a polymer film-based sealant such as ethylene vinyl acetate (EVA). The solar cell 230 may be protected from environmental factors by the vacuum V formed between the sealing member 220 and the solar cell 230, thereby increasing the lifespan of the solar cell 230. Adiabatic effects may occur due to the vacuum V, which may also increase the heat collecting efficiency of the solar energy utilizing apparatus 300.

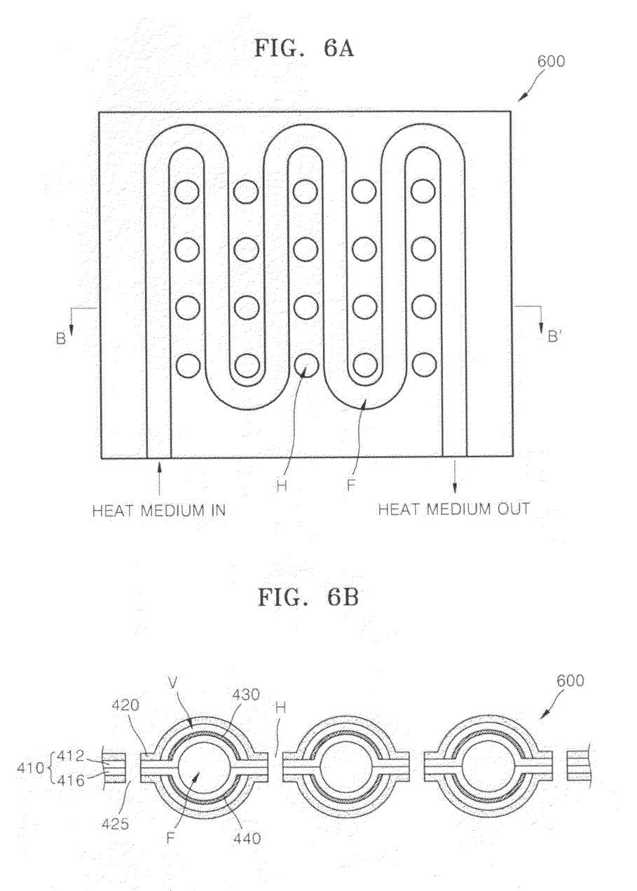

FIG. 4 is a cross-sectional view illustrating a solar energy utilizing apparatus according to another example embodiment.

Referring to FIG. 4, the solar energy utilizing apparatus 400 includes a fluid pipe 410. The fluid pipe 410 includes: a first substrate 412 in which a plurality of grooves are formed; and a second substrate 416 in which a plurality of grooves are also formed. The second substrate 416 is bonded to the first substrate 412 to form the fluid pipe 410.

In more detail with regard to FIG. 4, a plurality of convex surfaces 412a are formed on a surface of the first substrate 412, and a plurality of concave surfaces 412b are formed on an opposing surface of the first substrate 412. The plurality of concave surfaces 412b are formed to correspond to the plurality of the convex surfaces 412a, thereby forming a plurality of grooves.

A plurality of convex surfaces 416a are formed on a surface of the second substrate 416, and a plurality of concave surfaces 416b are formed on an opposing surface of the second substrate 416. The plurality of concave surfaces 416b are formed to correspond to the plurality of the convex surfaces 416a, thereby forming a plurality of grooves.

The first substrate 412 and the second substrate 416 are symmetrically bonded to each other about a bonding surface there between. As the first substrate 412 and the second substrate 416 are bonded, a plurality of inner spaces are formed. The plurality of inner spaces form a flow path F for a heat medium. A solar cell 430 is formed on the convex surfaces 412a of the first substrate 412. A solar cell 440 is also formed on the convex surfaces 416a of the second substrate 416. A light absorption layer (not shown) for enhancing heat collection may be formed on the convex surfaces 416a of the second substrate 416, instead of the solar cell 440.

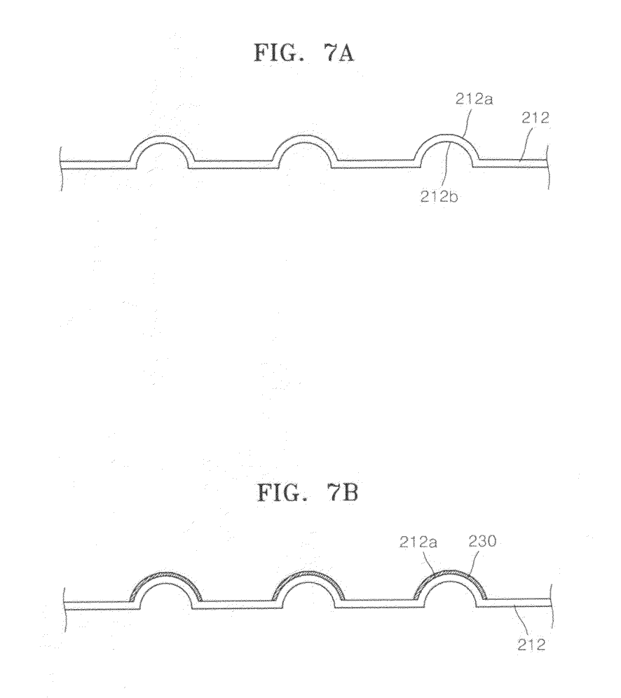

FIG. 5 is a cross-sectional view illustrating a solar energy utilizing apparatus according to another example embodiment. The solar energy utilizing apparatus 500 is similar to the solar energy utilizing apparatus 400 shown in FIG. 4 except that the solar energy utilizing apparatus 500 further includes sealing members 420 and 425. The sealing members 420 and 425 protect and/or insulate the solar cells 430 and 440, respectively, from the outside. A vacuum V may be formed between the sealing members 420 and 425 and the solar cells 430 and 440, respectively, thereby increasing the lifespan of the solar cell 230.

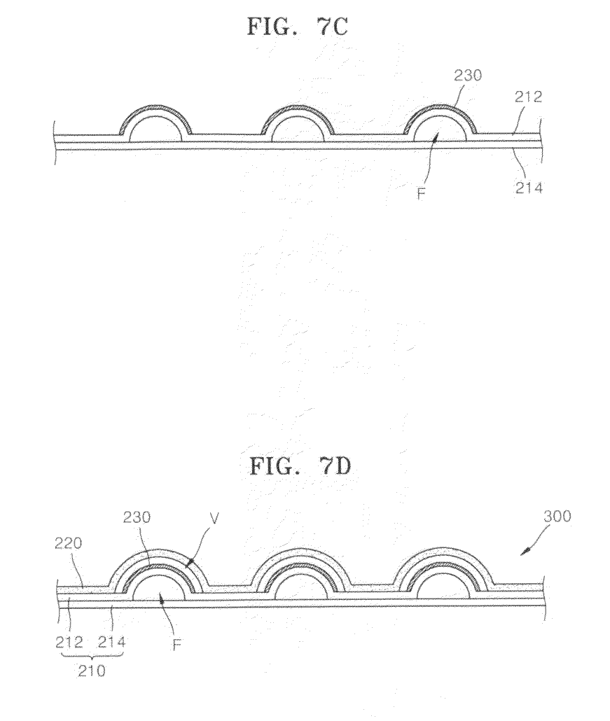

FIG. 6A is a plane view of a structure of a solar energy utilizing apparatus according to another example embodiment. FIG. 6B is a cross-sectional view taken along line B-B′ of FIG. 6A.

Referring to FIGS. 6A and 6B, the solar energy utilizing apparatus 600 includes a single flow path F, which is formed of a plurality of inner spaces. The plurality or inner spaces are formed by bonding a first substrate 412 and a second substrate 416 to one another. This configuration may be used for a flow path F capable of collecting solar heat over a broader surface area. Also, a plurality of through holes H are formed through the first substrate 412, the second substrate 416, and sealing members 420 and 425. The through holes H may reduce wind resistance when the solar energy utilizing apparatus 600 is installed as an external structure. The shape, number, and/or arrangement of the through holes H may be determined in consideration of reducing hydrodynamic resistance.

The solar energy utilizing apparatuses 100, 200, 300, 400, 500, and 600 according to example embodiments have a structure capable of generating electrical energy and heat energy from solar energy at the same time (e.g., simultaneously or concurrently). The structure may be implemented with lower costs relative to a thin film solar cell of the related art, and has relatively good energy efficiency. However, the solar energy utilizing apparatuses 100, 200, 300, 400, 500, and 600 are not limited to the above-described example embodiments. For example, various example embodiments may be configured from combinations of the above-described example embodiments. Also, various solar cell structures may be used, and other members such as a mirror member or a lens member for focusing solar light toward a solar cell and a fluid pipe may be used in combination.

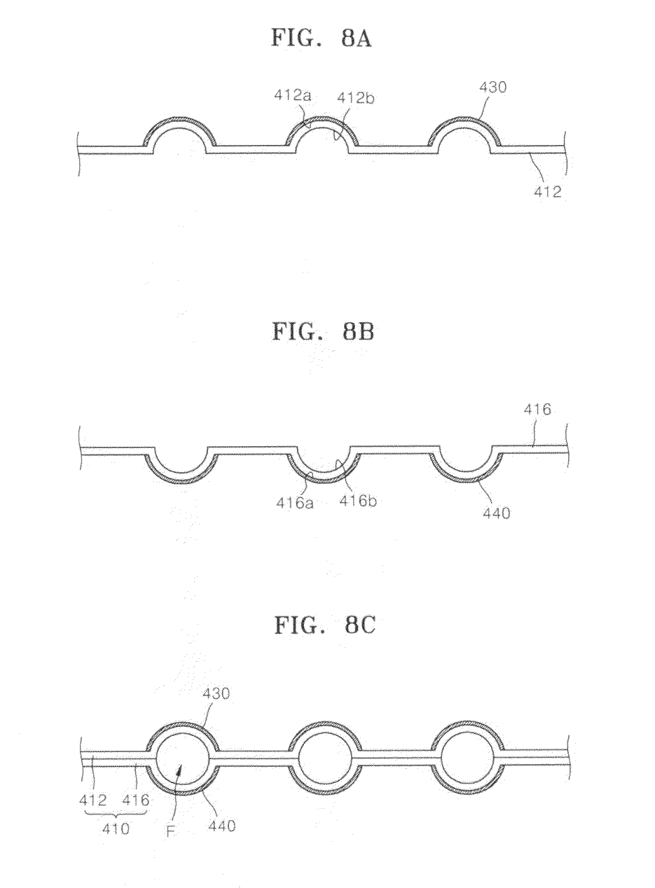

FIGS. 7A through 7D are cross-sectional views illustrating a method of manufacturing a solar energy utilizing apparatus according to an example embodiment. The method shown in FIGS. 7A through 7D may be used to manufacture the solar energy utilizing apparatus 300 described above.

Referring to FIG. 7A, a first substrate 212 is formed with grooves. The grooves are formed by convex surfaces 212a and concave surfaces 212b.

As shown in FIG. 7B, a solar cell 230 is formed on each of the convex surfaces 212a. The solar cell 230 is formed of a material such as a silicon semiconductor or various compound semiconductor materials, and using various methods such as a semiconductor growth method. For example, the solar cell 230 may be formed using a metal organic chemical vapor deposition (MOCVD) method, a hybrid vapor phase epitaxy (HVPE) method, a molecular beam epitaxy (MBE) method, a metal organic vapor phase epitaxy (MOVPE) method, a halide chemical vapor deposition (HCVD) method, etc.

Referring to FIG. 7C, a second substrate 214 is formed and bonded to the first substrate 212. As the first substrate 212 and the second substrate 214 are bonded to each other, inner spaces are formed. The inner spaces form flow paths F. In this example, the second substrate 214 is flat, but example embodiments are not limited thereto. For example, the second substrate 214 may include a plurality of grooves corresponding to the grooves of the first substrate 212. In this case, the first substrate 212 and the second substrate 214 are bonded to each other such that the grooves of the first substrate 212 and the grooves of the second substrate 214 face each other and are aligned with one another.

Referring to FIG. 7D, a sealing member 220 may be further included to protect and insulate the solar cell 230. A vacuum V formed by the vacuum sealing of the sealing member 220 may protect the solar cell 230 from the external environmental factors, thereby increasing the lifespan of the solar cell 230 and the heat collecting effect of the solar energy utilizing apparatus 300.

The solar energy utilizing apparatus 300 may be manufactured according to the operations described above with regard to FIGS. 7A through 7D.

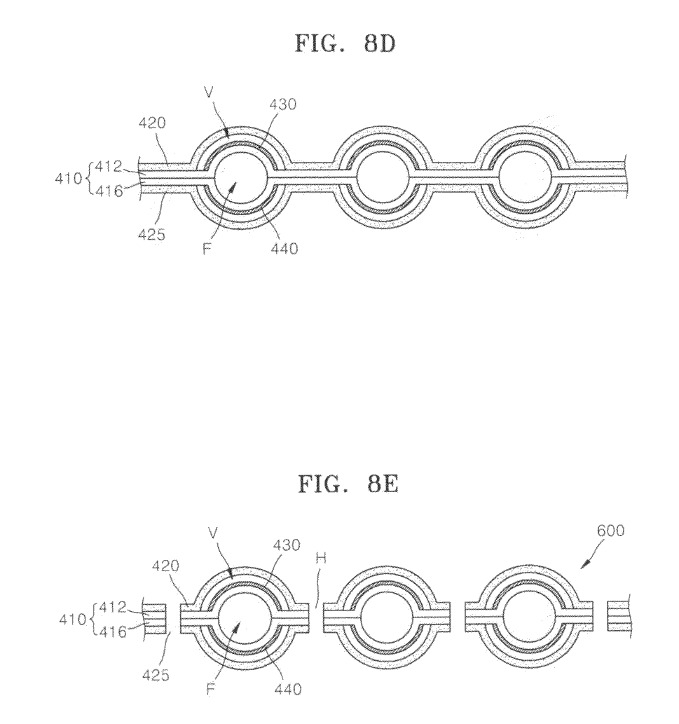

FIGS. 8A through 8E are cross-sectional views illustrating a method of manufacturing a solar energy utilizing apparatus according to another example embodiment. The method shown in FIGS. 8A through 8E may be used to manufacture the solar energy utilizing apparatus 600 described above.

Referring to FIG. 8A, a first substrate 412 is formed with grooves. Each groove has a convex surface 412a and a concave surface 412b. A solar cell 430 is formed on the convex surfaces 412a of the first substrate 412.

Referring to FIG. 8B, a second substrate 416 is also formed with grooves. Each of the grooves of the second substrate 416 have a convex surface 416a and a concave surface 416b that are similar or substantially similar to those of the first substrate 412. A solar cell 440 is formed on each convex surface 416a of the second substrate 416. A light absorption layer (not shown) may be formed on the convex surfaces 416a of the second substrate 416 instead of the solar cell 440.

Referring to FIG. 8C, the first substrate 412 and the second substrate 416 are bonded to each other, thereby forming a fluid pipe 410. The first substrate 412 and the second substrate 416 are symmetrically bonded to each other about a bonding surface. Inner spaces formed by the bonding of the first substrate 412 and the second substrate 416 accommodate a heat medium, and thus, form a flow path F for the heat medium.

Referring to FIG. 8D, sealing members 420 and 425, and the vacuum resulting there from, are formed to protect and insulate the solar cells 430 and 440.

Referring to FIG. 8E, a plurality of through holes H are formed through the sealing members 420 and 425, the first substrate 412, and the second substrate 416. The through holes H may reduce wind resistance when the solar energy utilizing apparatus 600 is installed as an external structure. The shape, number, or arrangement of the through holes H may be determined in consideration of reducing hydrodynamic resistance.

Thus, the solar energy utilizing apparatus 600 may be manufactured according to the operations described above.

According to at least some example embodiments, a solar energy utilizing apparatus having a structure in which solar heat and solar light may be used together is manufactured. At least some example embodiments, utilize a solar cell manufacturing process and a relatively simple process of bonding one or more substrates including grooves to one another.

It should be understood that example embodiments described herein should be considered in a descriptive sense only and not for purposes of limitation. Descriptions of features or aspects within each example embodiment should typically be considered as available for other similar features or aspects in other embodiments.

What is claimed is:

1. A solar energy utilizing apparatus comprising:
a fluid pipe forming a flow path for a heat medium, the fluid pipe having at least one convex surface; and
a solar cell formed on the at least one convex surface of the fluid pipe.

2. The solar energy utilizing apparatus of claim 1, further comprising:
a sealing member surrounding the solar cell.

3. The solar energy utilizing apparatus of claim 1, wherein the fluid pipe comprises:
a first substrate including,
a first surface on which a plurality of convex surfaces are formed, and
a second surface on which a plurality of concave surfaces are formed, the plurality of concave surfaces corresponding to the plurality of convex surfaces to form a first plurality of grooves; and
a second substrate bonded to the first substrate; wherein
a plurality of inner spaces formed by bonding of the first substrate and the second substrate form the flow path for a heat medium, and wherein
a plurality of solar cells are respectively formed on the plurality of the convex surfaces.

4. The solar energy utilizing apparatus of claim 3, wherein the second substrate comprises:
a second plurality of grooves; and wherein
the first substrate and the second substrate are bonded to each other such that the first plurality of grooves of the first substrate and the second plurality of grooves of the second substrate face and align with each other.

5. The solar energy utilizing apparatus of claim 4, wherein the second substrate has a plurality of convex surfaces and a plurality of concave surfaces of a same structure as the first substrate, and the first substrate and the second substrate are symmetrically bonded to each other about a bonding surface.

6. The solar energy utilizing apparatus of claim 5, wherein a plurality of solar cells are respectively formed on the plurality of convex surfaces of the second substrate.

7. The solar energy utilizing apparatus of claim 5, wherein a light absorption layer is formed on the plurality of convex surfaces of the second substrate.

8. The solar energy utilizing apparatus of claim 3, wherein the plurality of inner spaces are connected to one another to form a single flow path.

9. The solar energy utilizing apparatus of claim 3, further comprising:
a sealing member surrounding the plurality of solar cells.

10. The solar energy utilizing apparatus of claim 3, wherein a plurality of through holes are formed through the first and second substrates.

11. A method of manufacturing a solar energy utilizing apparatus, the method comprising:
forming a first substrate having a first surface and a second surface, the first surface including a plurality of convex surfaces, and the second surface having a plurality of concave surfaces, the plurality of concave surfaces corresponding to the plurality of convex surfaces to form a first plurality of grooves;
forming a plurality of solar cells on the plurality of convex surfaces, respectively; and
bonding a second substrate to the first substrate.

12. The method of claim 11, further comprising:
forming a second plurality of grooves in the second substrate; and wherein
the first substrate is bonded to the second substrate such that the first plurality of grooves of the first substrate and the second plurality of grooves of the second substrate face and align with each other.

13. The method of claim 12, further comprising:
forming the second plurality of grooves of the second substrate with a plurality of convex surfaces and a plurality of concave surfaces having a same structure as the convex and concave surfaces of the first substrate; wherein
the first substrate is symmetrically bonded to the second substrate about a bonding surface.

14. The method of claim 13, further comprising:
forming a plurality of solar cells on the plurality of convex surfaces of the second substrate.

15. The method of claim 13, further comprising:
forming a light absorption layer on the plurality of convex surfaces of the second substrate.

16. The method of claim 11, further comprising:
forming a sealing member surrounding the plurality of solar cells.

17. The method of claim 11, further comprising:
forming a plurality of through holes through the first and second substrates.
